(19) United States
(12) Patent Application Publication
(10) Pub. No.: US 2009/0251338 A1
(43) Pub. Date: Oct. 8, 2009

(54) Ink Tags In A Smart Pen Computing System

(75) Inventors: Jim Marggraff, Lafayette, CA (US); Alexander Sasha Pesic, San Ramon, CA (US)

Correspondence Address: FENWICK & WEST LLP, SILICON VALLEY CENTER, 801 CALIFORNIA STREET, MOUNTAIN VIEW, CA, 94041, US

(73) Assignee: LIVESCRIBE, INC., Oakland, CA (US)

(21) Appl. No.: 12/415,356

(22) Filed: Mar. 31, 2009

Related U.S. Application Data
(60) Provisional application No. 61/042,179, filed on Apr. 3, 2008.

(51) Int. Cl. H03K 17/94; H04M 1/00; G06K 9/00

(52) U.S. Cl. 341/20; 455/556.1; 382/187

(57) ABSTRACT

Embodiments of the invention present a system and method for generating digital links, or “ink tags,” from handwritten notes on a writing surface. Handwritten data, including one or more ink tags identifying digital content, is captured by a smart pen device and used to retrieve a digital document associated with the handwritten data. The handwritten data is analyzed to identify the ink tags. In one embodiment, a computing system performs optical character recognition on the handwriting data to identify a plurality of characters included in the handwriting data and compares one or more characters to formats associated with digital content. Responsive to identifying an ink tag, a digital link between the ink tag and a source for the digital content identified by the ink tag is generated, allowing the digital content to be retrieved by an interaction with the ink tag.

### CROSS REFERENCE TO RELATED APPLICATIONS

This application claims the benefit of U.S. Provisional Application No. 61/042,179, filed Apr. 3, 2008, which is incorporated by reference in its entirety.

### BACKGROUND

This invention relates generally to pen-based computing systems, and more particularly to generating digital links from handwritten data captured by a smart pen.

Using digital documents allows for highly efficient document storage and/or sharing. Digital documents include “links” allowing access to other digital documents or to various applications from the digital documents, simplifying access to these other digital documents or applications. For example, a digital document includes a hyperlink to a website Universal Resource Locator (URL). When a user accesses the hyperlink in the digital document, a web browser loads the corresponding website. In another example, a digital document includes an email address link so an email application opens when the email address is accessed by a user, allowing an email to be sent to the included email address. As another example, a digital document includes a link to a file, such as an audio or video file, locally stored on a computer or accessible via a network, so that the file is opened when the link is accessed via the digital document.

Use of digital links provides a convenient mechanism for including relevant or related information in a digital document in addition to the text and/or images in the digital document itself. However, the functionality of digital links is traditionally lost when digital documents are printed to a paper format. Furthermore, conventional technology does not allow incorporation of links into a document originating in a paper format. For example, if a student scans handwritten notes into a digital format, functioning links to additional resources cannot be included in the resulting digital document. Accordingly, there is a need for generating digital links from a document originating in a paper format.

### SUMMARY

Embodiments of the invention present a system and method for generating digital links, or “ink tags,” from handwritten notes on a writing surface. Handwritten data, including one or more ink tags identifying digital content, is captured by a smart pen device and used to retrieve a digital document associated with the handwritten data. The handwritten data is analyzed to identify the ink tags. In one embodiment, a computing system performs optical character recognition on the handwriting data to identify a plurality of characters included in the handwriting data and compares one or more characters to formats associated with digital content. Responsive to identifying an ink tag, a digital link between the ink tag and a source for the digital content identified by the ink tag is generated, allowing the digital content to be retrieved by an interaction with the ink tag.

### BRIEF DESCRIPTION OF THE DRAWINGS

FIG. 1 is a schematic diagram of a pen-based computing system in accordance with an embodiment of the invention.

FIG. 2 is a diagram of a smart pen for use in the pen-based computing system in accordance with an embodiment of the invention.

FIG. 3 is an event diagram of generation of ink tags from captured handwriting data in accordance with an embodiment of the invention.

The Figures depict various embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION

### Overview of Pen-Based Computing System

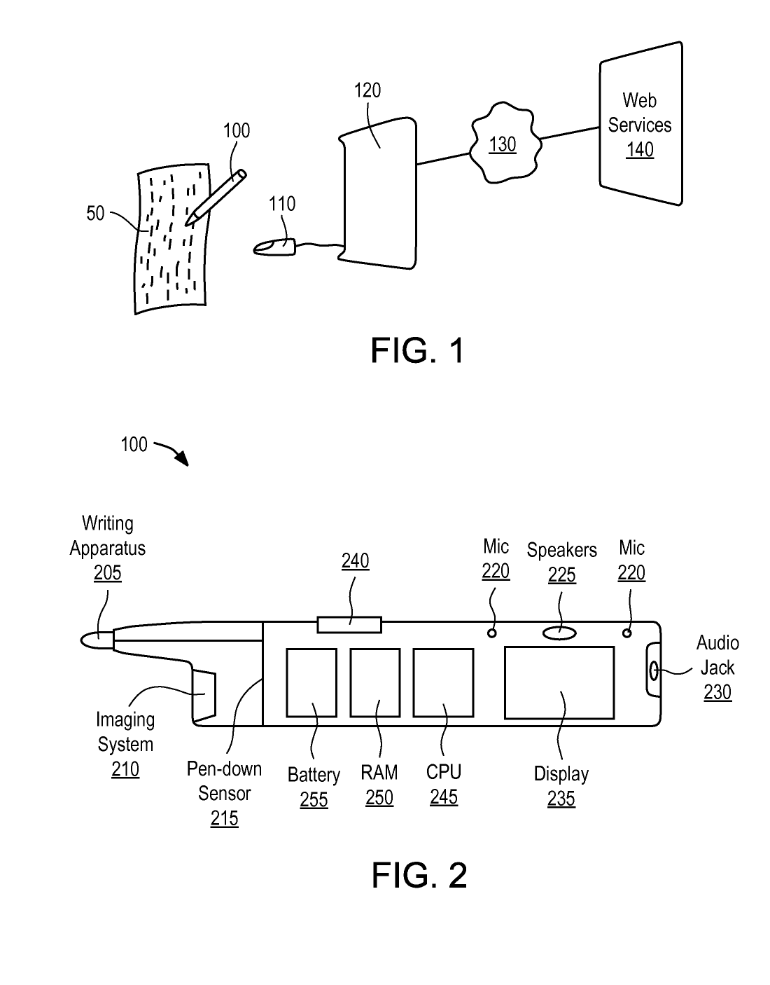

Embodiments of the invention may be implemented on various embodiments of a pen-based computing system, an example of which is illustrated in FIG. 1. In this embodiment, the pen-based computing system comprises a writing surface 50, a smart pen 100, a docking station 110, a client system 120, a network 130, and a web services system 140. The smart pen 100 includes onboard processing capabilities as well as input/output functionalities, allowing the pen-based computing system to expand the screen-based interactions of traditional computing systems to other surfaces on which a user can write. For example, the smart pen 100 may be used to capture electronic representations of writing as well as record audio during the writing, and the smart pen 100 may also be capable of outputting visual and audio information back to the user. With appropriate software on the smart pen 100 for various applications, the pen-based computing system thus provides a new platform for users to interact with software programs and computing services in both the electronic and paper domains, including electronic paper.

In the pen based computing system, the smart pen 100 provides input and output capabilities for the computing system and performs some or all of the computing functionalities of the system. Hence, the smart pen 100 enables user interaction with the pen-based computing system using multiple modalities. In one embodiment, the smart pen 100 receives input from a user, using multiple modalities, such as capturing a user's writing or other hand gesture or recording audio, and provides output to a user using various modalities, such as displaying visual information, playing audio or responding in context to physical interaction such as tapping, tracing, or selecting other pre-existing visual information. In other embodiments, the smart pen 100 includes additional input modalities, such as motion sensing or gesture capture, and/or additional output modalities, such as vibrational feedback. By receiving different types of input, the smart pen 100 may simultaneously capture different types of data, such as audio, movement and/or written or text, which can be used to generate a session including different types of data.

The components of a particular embodiment of the smart pen 100 are shown in FIG. 2 and described in more detail in the accompanying text. The smart pen 100 preferably has a form factor that is substantially shaped like a pen or other writing implement, although certain variations on the general shape may exist to accommodate other functions of the pen, or may even be an interactive multi-modal non-writing implement. For example, the smart pen 100 may be slightly thicker than a standard pen so that it can contain additional components, or the smart pen 100 may have additional structural features (e.g., a flat display screen) in addition to the structural features that form the pen shaped form factor. Additionally, the smart pen 100 may also include any mechanism by which a user can provide input or commands to the smart pen computing system or may include any mechanism by which a user can receive or otherwise observe information from the smart pen computing system. For example a variety of types of switches including buttons, rocker panels, capacitive sensors, heat sensors, pressure sensors, biometric sensors or other sensing devices could be added.

The smart pen 100 is designed to work in conjunction with the writing surface 50 so that the smart pen 100 can capture writing that is made on the writing surface 50. In one embodiment, the writing surface 50 comprises a sheet of paper (or any other suitable material that can be written upon) and is encoded with a pattern that can be read by the smart pen 100.

An example of such a writing surface 50 is the so-called “dot-enabled paper” available from Anoto Group AB of Sweden (local subsidiary Anoto, Inc. of Waltham, Mass.), and described in U.S. Pat. No. 7,175,095, incorporated by reference herein. This dot-enabled paper has a pattern of dots encoded on the paper. A smart pen 100 designed to work with this dot enabled paper includes an imaging system and a processor that can determine the position of the smart pen's writing tip with respect to the encoded dot pattern. This position of the smart pen 100 may be referred to using coordinates in a predefined “dot space,” and the coordinates can be either local (i.e., a location within a page of the writing surface 50) or absolute (i.e., a unique location across multiple pages of the writing surface 50).

In other embodiments, the writing surface 50 may be implemented using mechanisms other than encoded paper to allow the smart pen 100 to capture gestures and other written input. For example, the writing surface may comprise a tablet or other electronic medium that senses writing made by the smart pen 100. In another embodiment, the writing surface 50 comprises electronic paper, or e-paper. This sensing may be performed entirely by the writing surface 50, entirely by the smart pen 100, or in conjunction with the smart pen 100. Even if the role of the writing surface 50 is only passive (as in the case of encoded paper), it can be appreciated that the design of the smart pen 100 will typically depend on the type of writing surface 50 for which the pen based computing system is designed. Moreover, written content may be displayed on the writing surface 50 mechanically (e.g., depositing ink on paper using the smart pen 100), electronically (e.g., displayed on the writing surface 50), or not at all (e.g., merely saved in a memory). In another embodiment, the smart pen 100 is equipped with sensors to sense movement of the smart pen 100 tip, thereby sensing writing gestures without requiring a writing surface 50 at all. Any of these technologies may be used in a gesture capture system incorporated in the smart pen 100. For example, handwriting marks or other gestures made on the writing surface 50 are captured and recorded by the gesture capture system incorporated in the smart pen 100.

In various embodiments, the smart pen 100 can communicate with a general purpose computing system 120, such as a personal computer, for various useful applications of the pen based computing system. For example, content, such as handwriting marks or other gestures, captured by the smart pen 100 may be transferred to the computing system 120 for further use by the computing system 120. For example, the computing system 120 may include management software that allows a user to store, access, review, delete, and otherwise manage the information acquired by the smart pen 100. As another example, the computing system 120 generates a digital representation of a paper document using data captured by the smart pen, allowing generation of a digital document from handwriting captured by the smart pen 100. Alternatively, the smart pen 100 captures data from a paper document having a corresponding digital document stored in a database accessible by the computing system 120. By using the smart pen 100, a user can annotate the paper document, and the annotations are captured by the smart pen 100 and communicated to the computing system 120 which incorporates the captured annotations into the digital document corresponding to the paper document. In one embodiment, the web services 140 comprises a digital document database which stores digital documents for retrieval by the computing system 120. Alternatively, the computing system 120 includes the digital document database.

In an embodiment, the handwriting captured by the smart pen 100 includes one or more “ink tags” indicating handwritten data to be converted into a link in the digital document corresponding to the captured handwriting. For example, the smart pen 100 captures handwriting data including an ink tag associated with a Uniform Resource Locator (URL) from the writing surface 50. The captured handwriting data is communicated to the computing system 120 which generates a corresponding digital document from the captured handwriting data. As the digital document is generated, the computing system 120 identifies the ink tag and generates a digital link to the content identified by the ink tag. In this example, the computing system 120 generates a hyperlink to the URL associated with the ink tag, allowing the user to access the website associated with the URL from the generated digital document.

Downloading acquired data from the smart pen 100 to the computing system 120 also frees the resources of the smart pen 100 so that it can acquire more data. Conversely, content may also be transferred back onto the smart pen 100 from the computing system 120. In addition to data, the content provided by the computing system 120 to the smart pen 100 may include software applications that can be executed by the smart pen 100.

The smart pen 100 may communicate with the computing system 120 via any of a number of known communication mechanisms, including both wired and wireless communications, such as Bluetooth, WiFi, RF, infrared and ultrasonic sound. In one embodiment, the pen based computing system includes a docking station 110 coupled to the computing system. The docking station 110 is mechanically and electrically configured to receive the smart pen 100, and when the smart pen 100 is docked the docking station 110 may enable electronic communications between the computing system 120 and the smart pen 100. The docking station 110 may also provide electrical power to recharge a battery in the smart pen 100.

FIG. 2 illustrates an embodiment of the smart pen 100 for use in a pen based computing system, such as the embodiments described above. In the embodiment shown in FIG. 2, the smart pen 100 comprises a marker 205, an imaging system 210, a pen down sensor 215, one or more microphones 220, a speaker 225, an audio jack 230, a display 235, an I/O port 240, a processor 245, an onboard memory 250, and a battery 255. It should be understood, however, that not all of the above components are required for the smart pen 100, and this is not an exhaustive list of components for all embodiments of the smart pen 100 or of all possible variations of the above components. For example, the smart pen 100 may also employ buttons, such as a power button or an audio recording button and/or status indicator lights. Moreover, as used herein in the specification and in the claims, the term “smart pen” does not imply that the pen device has any particular feature or functionality described herein for a particular embodiment, other than those features expressly recited. A smart pen may have any combination of fewer than all of the capabilities and subsystems described herein.

The marker 205 enables the smart pen to be used as a traditional writing apparatus for writing on any suitable surface. The marker 205 may thus comprise any suitable marking mechanism, including any ink-based or graphite-based marking devices or any other devices that can be used for writing. In one embodiment, the marker 205 comprises a replaceable ballpoint pen element. The marker 205 is coupled to a pen down sensor 215, such as a pressure sensitive element. The pen down sensor 215 thus produces an output when the marker 205 is pressed against a surface, thereby indicating when the smart pen 100 is being used to write on a surface.

The imaging system 210 comprises sufficient optics and sensors for imaging an area of a surface near the marker 205. The imaging system 210 may be used to capture handwriting and/or gestures made with the smart pen 100. For example, the imaging system 210 may include an infrared light source that illuminates a writing surface 50 in the general vicinity of the marker 205, where the writing surface 50 includes an encoded pattern. By processing the image of the encoded pattern, the smart pen 100 can determine where the marker 205 is in relation to the writing surface 50. An imaging array of the imaging system 210 then images the surface near the marker 205 and captures a portion of a coded pattern in its field of view. Thus, the imaging system 210 allows the smart pen 100 to receive data using at least one input modality, such as receiving written input. The imaging system 210 incorporating optics and electronics for viewing a portion of the writing surface 50 is just one type of gesture capture system that can be incorporated in the smart pen 100 for electronically capturing any writing gestures made using the pen, and other embodiments of the smart pen 100 may use other appropriate means for achieving the same function. In an embodiment, data captured by the imaging system 210 is subsequently processed, allowing one or more content recognition algorithms, such as character recognition, to be applied to the received data.

In an embodiment, data captured by the imaging system 210 is subsequently processed, allowing one or more content recognition algorithms, such as character recognition, to be applied to the received data. In another embodiment, the imaging system 210 can be used to scan and capture written content that already exists on the writing surface 50 (e.g., and not written using the smart pen 100). The imaging system 210 may further be used in combination with the pen down sensor 215 to determine when the marker 205 is touching the writing surface 50. As the marker 205 is moved over the surface, the pattern captured by the imaging array changes, and the user's handwriting can thus be determined and captured by a gesture capture system (e.g., the imaging system 210 in FIG. 2) in the smart pen 100. This technique may also be used to capture gestures, such as when a user taps the marker 205 on a particular location of the writing surface 50, allowing data capture using another input modality of motion sensing or gesture capture.

The imaging system 210 may further be used in combination with the pen down sensor 215 to determine when the marker 205 is touching the writing surface 50. As the marker 205 is moved over the surface, the pattern captured by the imaging array changes, and the user's handwriting can thus be determined and captured by the smart pen 100. This technique may also be used to capture gestures, such as when a user taps the marker 205 on a particular location of the writing surface 50, allowing data capture using another input modality of motion sensing or gesture capture.

Another data capture device on the smart pen 100 are the one or more microphones 220, which allow the smart pen 100 to receive data using another input modality, audio capture. The microphones 220 may be used for recording audio, which may be synchronized to the handwriting capture described above. In an embodiment, the one or more microphones 220 are coupled to signal processing software executed by the processor 245, or by a signal processor (not shown), which removes noise created as the marker 205 moves across a writing surface and/or noise created as the smart pen 100 touches down to or lifts away from the writing surface.

In an embodiment, the processor 245 synchronizes captured written data with captured audio data. Hence, in an operating mode, the microphones 220 record audio when the imaging system 210 captures writing by the smart pen 100, allowing automatic capture of audio data when the imaging system 210 is capturing handwriting data. In this operating mode, the microphones 220 stop capturing audio data when the imaging system 210 stops capturing handwriting data. Alternatively, the microphones 220 record audio responsive to the imaging system 210 capturing a command included in the handwriting data.

For example, a conversation in a meeting may be recorded using the microphones 220 while a user is taking notes that are also being captured by the smart pen 100. Synchronizing recorded audio and captured handwriting allows the smart pen 100 to provide a coordinated response to a user request for previously captured data. For example, responsive to a user request, such as a written command, parameters for a command, a gesture with the smart pen 100, a spoken command or a combination of written and spoken commands, the smart pen 100 provides both audio output and visual output to the user. The smart pen 100 may also provide haptic feedback to the user.

However, to record audio using the microphones 220 when the smart pen 100 is not used for writing, the smart pen 100 also includes a secondary recording method allowing a user to initiate a “quick record” mode which causes the microphones 220 to capture audio when the smart pen 100 is not used for writing. The quick record mode can be stopped responsive to a user input to stop the microphones 220 from recording audio. Alternatively, the quick record mode stops audio capture after a predetermined time interval from initiation of the quick record mode.

The speaker 225, audio jack 230, and display 235 provide outputs to the user of the smart pen 100 allowing presentation of data to the user via one or more output modalities. The audio jack 230 may be coupled to earphones so that a user may listen to the audio output without disturbing those around the user, unlike with a speaker 225. Earphones may also allow a user to hear the audio output in stereo or full three-dimensional audio that is enhanced with spatial characteristics. Hence, the speaker 225 and audio jack 230 allow a user to receive data from the smart pen using a first type of output modality by listening to audio played by the speaker 225 or the audio jack 230.

The display 235 may comprise any suitable display system for providing visual feedback, such as an organic light emitting diode (OLED) display, allowing the smart pen 100 to provide output using a second output modality by visually displaying information. In use, the smart pen 100 may use any of these output components to communicate audio or visual feedback, allowing data to be provided using multiple output modalities. For example, the speaker 225 and audio jack 230 may communicate audio feedback (e.g., prompts, commands, and system status) according to an application running on the smart pen 100, and the display 235 may display word phrases, static or dynamic images, or prompts as directed by such an application. In addition, the speaker 225 and audio jack 230 may also be used to play back audio data that has been recorded using the microphones 220.

The input/output (I/O) port 240 allows communication between the smart pen 100 and a computing system 120, as described above. In one embodiment, the I/O port 240 comprises electrical contacts that correspond to electrical contacts on the docking station 110, thus making an electrical connection for data transfer when the smart pen 100 is placed in the docking station 110. In another embodiment, the I/O port 240 simply comprises a jack for receiving a data cable (e.g., Mini-USB or Micro-USB). Alternatively, the I/O port 240 may be replaced by a wireless communication circuit in the smart pen 100 to allow wireless communication with the computing system 120 (e.g., via Bluetooth, WiFi, infrared, or ultrasonic).

A processor 245, onboard memory 250, and battery 255 (or any other suitable power source) enable computing functionalities to be performed at least in part on the smart pen 100. The processor 245 is coupled to the input and output devices and other components described above, thereby enabling applications running on the smart pen 100 to use those components. In one embodiment, the processor 245 comprises an ARM9 processor, and the onboard memory 250 comprises a small amount of random access memory (RAM) and a larger amount of flash or other persistent memory. As a result, executable applications can be stored and executed on the smart pen 100, and recorded audio and handwriting can be stored on the smart pen 100, either indefinitely or until offloaded from the smart pen 100 to a computing system 120. For example, the smart pen 100 may locally stores one or more content recognition algorithms, such as character recognition or voice recognition, allowing the smart pen 100 to locally identify input from one or more input modality received by the smart pen 100.

In an embodiment, the smart pen 100 also includes an operating system or other software supporting one or more input modalities, such as handwriting capture, audio capture or gesture capture, or output modalities, such as audio playback or display of visual data. The operating system or other software may support a combination of input modalities and output modalities and manages the combination, sequencing and transitioning between input modalities (e.g., capturing written and/or spoken data as input) and output modalities (e.g., presenting audio or visual data as output to a user). For example, this transitioning between input modality and output modality allows a user to simultaneously write on paper or another surface while listening to audio played by the smart pen 100, or the smart pen 100 may capture audio spoken from the user while the user is also writing with the smart pen 100.

In an embodiment, the operating system and applications support a sequence of independent and/or concurrent input and output modalities and seamless transitions between these modalities to provide for language learning. For example, a language learning (LL) application running on an operating system supporting modality independence, concurrence and sequencing might begin a lesson announcing that today is a lesson in writing, reading, speaking and listening to Chinese. The smart pen 100 might then animate the creation of a Mandarin character, drawing strokes of the character in proper order on the display 235, while simultaneously announcing the character's pronunciation via the speaker 225. The operating system would enable the simultaneous display and synchronized delivery of audio. The LL application might then prompt the user to draw each stroke of the character, following the animated display of each stroke on the display 225, thus sequencing the transition between modalities of visual output of information displayed on the smart pen 100, in a synchronized manner, with the input of stroke data by a user. As the user becomes more fluent with the creations of the character, and begins writing more rapidly, perhaps writing ahead of the strokes displayed, the OS will enable real time capture and interpretation of strokes and respond with proper displaying and audio as appropriate, engaging the user in a multimodal dialogue. As the user demonstrates proficiency in writing, and the smart pen 100 begins to be lead by the user, displaying strokes in response, rather than leading with strokes, the smart pen 100 might verbally compliment the user and request the user to speak the sound for the character during or after the stroke writing. As the user speaks the character sound, the smart pen 100 could record the sound and compare it to an exemplar. The smart pen 100 might then prompt the user by playing back the exemplar pronunciation and the user pronunciation, providing commentary and/or visual guidance regarding correctness in pronunciation The smart pen 100 might then prompt the user to listen, write, and speak, announcing a series of words one by one, waiting for the user to write and speak the words, while comparing the input speech and writing to exemplars, and redirecting the user to repeat writing or speaking as necessary.

In an extension of this example, the smart pen 100 might prompt the user to interact with a pre-printed Language Learning text or workbook. The smart pen 100 might move the user's attention among multiple displays, from text, to the workbook, to a user's notebook, while continuing a dialogue involving the smart pen 100 speaking and displaying independently or concurrently, directing the user to speak, write, and look at information independently or concurrently. Various other combinations of input modalities and output modalities, and sequencing, are also possible.

In an embodiment, the processor 245 and onboard memory 250 include one or more executable applications supporting and enabling a menu structure and navigation through a file system or application menu, allowing launch of an application or of a functionality of an application. For example, navigation between menu items comprises a dialogue between the user and the smart pen 100 involving spoken and/or written commands and/or gestures by the user and audio and/or visual feedback from the smart pen computing system. Hence, the smart pen 100 may receive input to navigate the menu structure from a variety of modalities.

For example, a writing gesture, a spoken keyword or a physical motion, may indicate that subsequent input is associated with one or more application commands. Input with a spatial and/or temporal component may also be used to indicate that subsequent data. Examples of input with a spatial input include two dots side-by-side. Examples of input with a temporal component include two dots written one immediately after the other. For example, a user may depress the smart pen 100 against a surface twice in rapid succession then write a word or phrase, such as “solve,” “send,” “translate,” “email,” “voice-email” or another predefined word or phrase to invoke a command associated with the written word or phrase or receive additional parameters associated with the command associated with the predefined word or phrase. Because these “quick-launch” commands can be provided in different formats, navigation of a menu or launching of an application is simplified. The “quick-launch” command or commands are preferably easily distinguishable during conventional writing and/or speech.

Alternatively, the smart pen 100 also includes a physical controller, such as a small joystick, a slide control, a rocker panel, a capacitive (or other non-mechanical) surface or other input mechanism which receives input for navigating a menu of applications or application commands executed by the smart pen 100.

Generation of Links from Ink Tags

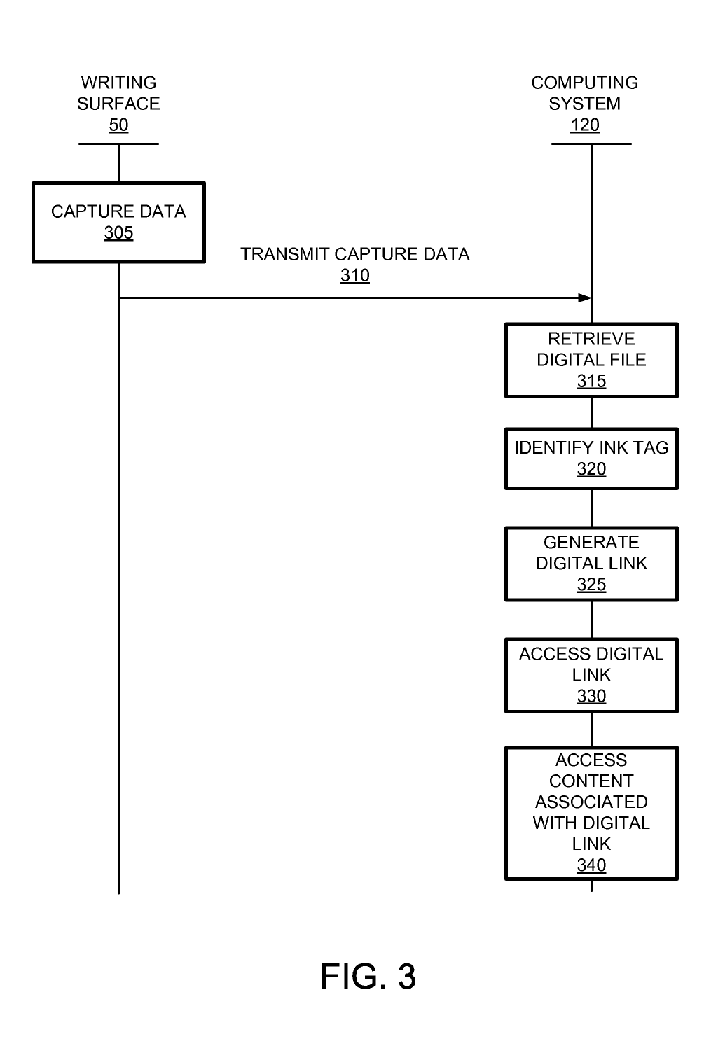

FIG. 3 is an event diagram of a process for generating ink tags from captured handwriting data in accordance with an embodiment of the invention. Those of skill in the art will recognize that other embodiments can include different and/or additional steps than the ones described here. For purposes of illustration, FIG. 3 depicts certain steps as performed by a computing system 120. However, in other embodiments, one or more of the illustrated steps are performed by a smart pen 100. Further, the steps depicted in FIG. 3 are implemented by instructions for performing the described actions embodied or stored within a computer readable medium, such as onboard memory 250, that are executable by a processor, such as processor 245. Those of skill in the art will recognize that the steps shown in FIG. 3 may be implemented in embodiments of hardware and/or software or combinations thereof.

Handwriting data is captured 305 from a writing surface 50 by a smart pen 100. The captured handwriting data includes one or more ink tags identifying handwriting data corresponding to links in a corresponding digital document or portion of a digital document, such as a phone number or email address. The captured handwriting data is transmitted 310 from the smart pen 100 to a computing system 120. In one embodiment, the captured data is transmitted 310 to the computing system 120 via any of a number of known communication mechanisms, including both wired and wireless communications, such as Bluetooth, WiFi, RF, infrared and ultrasonic sound. Alternatively, a docking station 110 is used to transmit captured data from the smart pen 100 to the computing system 120. The docking station 110 is mechanically and electrically configured to receive the smart pen 100, and when the smart pen 100 is docked the docking station 110 enables electronic communications between the computing system 120 and the smart pen 100.

After receiving the captured data from the smart pen 100, the computing system 120 retrieves 315 a digital file associated with the captured data. In one embodiment, the computing system 120 generates a digital file from the captured handwriting data. Alternatively, the computing system 120 accesses a digital document database and retrieves 315 an existing digital file associated with the captured handwriting data. One or more ink tags included in the captured handwriting data are then identified 320. In an embodiment, an ink tag is identified 320 using optical character recognition (OCR) executing on the smart pen 100 or the computing system 120. OCR translates handwritten text into machine-readable characters, such as ASCII characters and, in an embodiment, OCR also examines a format associated with one or more characters and uses the format to identify ink tags in the captured handwriting data. Hence, characteristics or attributes of the handwriting data identify the one or more ink tags. For example, handwriting data including the characters “http” or “www” are identified 320 as ink tags associated with hyperlinks. As another example, handwriting including data formatted as “name company.xxx” is identified 320 as an ink tag associated with an email address. In other embodiments, a predefined set of markups included in the handwriting data are used by the OCR to identify 320 an ink tag. For example, underlined text is identified as an ink tag, or text including a specified symbol is identified as an ink tag. As another example, the smart pen 100 captures a gesture or interacts with a control, such as a printed control on the writing surface, when written data is produced, allowing the captured gesture or control interaction to identify the written data as an ink tag. In an embodiment, the type of gesture or interaction with a control also associates a type with the ink tag, identifying the ink tag as a contact, a link to web content, a document or otherwise associated with data, allowing the computing system 120 to identify both the content of the ink tag and the type associated with the ink tag using data captured by the smart pen 100. This allows additional data captured by the smart pen 100 to identify the ink tag in addition to content included in the captured written data.

A digital link is then generated 325 and associated with the identified ink tag. This digital link allows access to content, such as a web page, email address, media file, other data file or information type information type, by interacting with the digital link. Responsive to the digital link being accessed 330, the content associated with the digital link is accessed 340. For example, if the digital link is accessed 330, a web browser is launched to access a website associated 340 with the digital link, an email client is launched to compose an email to the identified address or a file associated with the digital link is accessed 340. In an embodiment, the digital link may be accessed 330 by interaction with the handwritten data on the writing surface 50. If the computing system 120 identifies 320 an ink tag, the identified ink tag is communicated back to the smart pen 100, allowing the digital link associated with the ink tag to be later accessed by the smart pen 100 interaction with the written data identified as an ink tag on the writing surface 50. For example, tapping the smart pen 100 on an ink tag on the writing surface 50 after generation 325 of a corresponding digital link causes the smart pen 100 to communicate with the computing system 120 and access 340 the content associated with the digital link. In another embodiment, the smart pen 100 directly accesses 340 the digital link. For example, the smart pen 100 taps an email address or phone number included in the written data to add the email address to a contact list locally stored on the smart pen 100. As another example, accessing written data with the smart pen 100 opens a pen-based calendar program. In an embodiment, the smart pen 100 wirelessly accesses the computing system 120 to access functions or applications associated with an ink tag accessed by the smart pen 100. Alternatively, clicking or otherwise accessing 330 the digital link using the computing system 120 accesses 340 the content associated with the digital link.

In an embodiment, accessing 330 the digital link causes the smart pen 100 or computing system 120 to communication with a mobile phone or other mobile device to access 340 the content associated with the digital link. In an embodiment, when a user taps on a handwritten ink tag on the writing surface 50, the smart pen 100 communicates to the mobile phone or other mobile device, causing the mobile phone to access 330 the digital link corresponding to the ink tag and subsequently access 340 the content associated an ink tag captured 305 by the smart pen 100. For example, when the smart pen 100 taps an ink tag associated with a web page, the mobile phone or other mobile device accesses 340 the corresponding web page.

In another embodiment, the smart pen 100 captures 205 handwriting data associated with a telephone number and dials the telephone. OCR is used by the smart pen 100 or the computing system 120 to identify 320 an ink tag associated with the telephone number from the captured handwriting data. In an embodiment, the OCR compares a format of the handwriting data to one or more formats associated with telephone numbers. For example, the OCR determines whether the handwriting data includes a sequence of characters having a format such as “(XXX) XXX-XXXX,” “XXX-XXX-XXXX” or another format associated with a telephone number. In an embodiment, the smart pen 100 includes a wireless transceiver allowing wireless communication using WiFi, WiMAX, GSM, CDMA, TDMA, 3G or other wireless communication format and dials the telephone number from the captured handwriting data by wirelessly connecting to the internet. As the smart pen 100 also includes one or more speakers 225, one or more microphones 220 and a display 235, the smart pen 100 can be used as a mobile phone. Alternatively, the smart pen 100 is wirelessly paired to a cellular phone, a VoIP enabled computer or a VoIP mobile phone, so that accessing the ink tag with the smart pen 100 causes the cellular phone, VoIP enabled computer or VoIP mobile phone to dial the telephone number.

### Summary

The foregoing description of the embodiments of the invention has been presented for the purpose of illustration; it is not intended to be exhaustive or to limit the invention to the precise forms disclosed. Persons skilled in the relevant art can appreciate that many modifications and variations are possible in light of the above disclosure.

Some portions of this description describe the embodiments of the invention in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all of the steps, operations, or processes described.

Embodiments of the invention may also relate to an apparatus for performing the operations herein. This apparatus may be specially constructed for the required purposes, and/or it may comprise a general-purpose computing device selectively activated or reconfigured by a computer program stored in the computer. Such a computer program may be stored in a tangible computer readable storage medium, which include any type of tangible media suitable for storing electronic instructions, and coupled to a computer system bus. Furthermore, any computing systems referred to in the specification may include a single processor or may be architectures employing multiple processor designs for increased computing capability.

Embodiments of the invention may also relate to a computer data signal embodied in a carrier wave, where the computer data signal includes any embodiment of a computer program product or other data combination described herein. The computer data signal is a product that is presented in a tangible medium or carrier wave and modulated or otherwise encoded in the carrier wave, which is tangible, and transmitted according to any suitable transmission method.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based hereon. Accordingly, the disclosure of the embodiments of the invention is intended to be illustrative, but not limiting, of the scope of the invention, which is set forth in the following claims.

What is claimed is:

1. A pen-based computing system for generating a digital link from captured written data comprising:
a smart pen device configured to capture audio data and written data, the written data including an ink tag associated with digital content; and
a computer system coupled to the smart pen device, the computer system comprising a processor, a storage medium, and computer program instructions stored on the storage medium for causing the processor to:
retrieve a digital file containing the captured written data,
identify an ink tag within the captured written data, wherein the ink tag comprises a portion of the captured written data that contains a digital link, and
adding the ink tag to the digital file so that the identified digital link is associated with the portion of the captured written data that contains the digital link.

2. The pen-based computing system of claim 1, wherein the computer system further comprises instructions stored on the storage medium for causing the processor to:
retrieve the digital content associated with the ink tag from the source responsive to receiving an input accessing the ink tag or the digital link.

3. The pen-based computing system of claim 1, wherein the digital content associated with the ink tag comprises a telephone number.

4. The pen-based computing system of claim 3, further comprising a mobile phone coupled to the smart pen for dialing the telephone number responsive to the smart pen accessing the ink tag associated with the telephone number.

5. The pen-based computing system of claim 3, wherein smart pen dials the telephone number responsive to accessing the ink tag associated with the telephone number.

6. The pen-based computing system of claim 1, wherein the digital content associated with the ink tag comprises a website address.

7. The pen-based computing system of claim 1, wherein the computer system accesses the website associated with the website address responsive to the smart pen accessing the ink tag associated with the website address.

8. The pen-based computing system of claim 1, wherein the instructions for identifying an ink tag within the captured written data comprise instructions for:
applying an optical character recognition method to the captured written data to identify a plurality of characters comprising the written data; and
comparing the plurality of characters to one or more predefined formats associated with digital content.

9. The pen-based computing system of claim 8 wherein the one or more predefined formats comprise a format associated with an email address, a format associated with a website, a format associated with a telephone number and a format associated with a filename.

10. The pen-based computing system of claim 1, further comprising a digital document database coupled to the computing system for storing one or more digital documents.

11. A method for generating a digital link from data captured by a smart pen device comprising:
receiving handwriting data captured by a smart pen device, the handwriting data stored in a digital document;
identifying an ink tag within the captured written data, wherein the ink tag comprises a portion of the captured written data that contains a digital link, and
adding the ink tag to the digital file so that the identified digital link is associated with the portion of the captured written data that contains the digital link.

12. The method of claim 11, further comprising:
receiving an input accessing the ink tag or digital ink associated with the ink tag; and
retrieving the digital content associated with the ink tag from the source for the digital content.

13. The method of claim 12, wherein retrieving the digital content associated with the ink tag from the source for the digital content comprises:
dialing a telephone number associated with the ink tag using a communication device coupled to the smart pen device.

14. The method of claim 12, wherein retrieving the digital content associated with the ink tag from the source for the digital content comprises:
dialing a telephone number associated with the ink tag using the smart pen device.

15. The method of claim 12, wherein retrieving the digital content associated with the ink tag from the source for the digital content comprises:
accessing a website associated with the ink tag using a computing system coupled to the smart pen device.

16. The method of claim 12, wherein retrieving the digital content associated with the ink tag from the source for the digital content comprises:
accessing a digital document database including the digital content;
receiving the digital content from the digital document database; and
displaying the digital content.

17. The method of claim 11, wherein identifying the ink tag within the captured written data comprises:
applying an optical character recognition method to the handwriting data to identify a plurality of characters comprising the handwriting data; and
comparing the plurality of characters to one or more predefined formats associated with digital content.

18. The method of claim 17, wherein the one or more predefined formats comprise a format associated with an email address, a format associated with a website, a format associated with a telephone number and a format associated with a filename.

19. A computer program product comprising computer program code stored on a memory and configured to be executed by a processor coupled to a smart pen device for generating a digital link from data captured by a smart pen device comprising, the computer program code including instructions for:
receiving handwriting data captured by a smart pen device, the handwriting data stored in a digital document;
identifying an ink tag within the captured written data, wherein the ink tag comprises a portion of the captured written data that contains a digital link, and
adding the ink tag to the digital file so that the identified digital link is associated with the portion of the captured written data that contains the digital link.

20. The computer program product of claim 19, further comprising instructions for:
receiving an input accessing the ink tag or digital ink associated with the ink tag; and
retrieving the digital content associated with the ink tag from the source for the digital content.

21. The computer program product of claim 20, wherein retrieving the digital content associated with the ink tag from the source for the digital content comprises:
dialing a telephone number associated with the ink tag using a communication device coupled to the smart pen device.

22. The computer program product of claim 20, wherein retrieving the digital content associated with the ink tag from the source for the digital content comprises:
dialing a telephone number associated with the ink tag using the smart pen device.

23. The computer program product of claim 20, wherein retrieving the digital content associated with the ink tag from the source for the digital content comprises:
accessing a website associated with the ink tag using a computing system coupled to the smart pen device.

24. The computer program product of claim 20, wherein retrieving the digital content associated with the ink tag from the source for the digital content comprises:
accessing a digital document database including the digital content;
receiving the digital content from the digital document database; and
displaying the digital content.

25. The computer program product of claim 19, wherein identifying the ink tag within the captured written data comprises:
applying an optical character recognition method to the handwriting data to identify a plurality of characters comprising the handwriting data; and
comparing the plurality of characters to one or more predefined formats associated with digital content.

26. The computer program product of claim 25, wherein the one or more predefined formats comprise a format associated with an email address, a format associated with a website, a format associated with a telephone number and a format associated with a filename.
